(19) United States
(12) Patent Application Publication
(10) Pub. No.: US 2025/0159868 A1
(43) Pub. Date: May 15, 2025

(54) SEMICONDUCTOR DEVICE

(71) Applicant: SAMSUNG ELECTRONICS CO., LTD., Suwon-si (KR)

(72) Inventors: Selyung Yoon, Suwon-si (KR); Daehyeon Kwon, Suwon-si (KR); Donggeon Kim, Suwon-si (KR); Bok-Yeon Won, Suwon-si (KR)

(21) Appl. No.: 18/783,044

(22) Filed: Jul. 24, 2024

(30) Foreign Application Priority Data
Nov. 14, 2023 (KR) 10-2023-0157636

(51) Int. Cl. H10B 12/00; H01L 23/522

(52) U.S. Cl. CPC H10B 12/482; H01L 23/5225; H10B 12/0335; H10B 12/315; H10B 12/50

(57) ABSTRACT

A semiconductor device includes a substrate, a transistor on the substrate, a bit line structure electrically connected to the transistor, a channel layer on the bit line structure, a gate structure intersecting the bit line structure, a first conductive line electrically connecting the transistor and the bit line structure, an upper shield line overlapping the first conductive line, and side shield lines spaced apart from each other with the first conductive line interposed therebetween. The upper shield line and the side shield lines are electrically separated from the first conductive line and the bit line structure.

### CROSS-REFERENCE TO RELATED APPLICATION

This application claims priority under 35 U.S.C. § 119 to Korean Patent Application No. 10-2023-0157636, filed on Nov. 14, 2023, in the Korean Intellectual Property Office, the entire contents of which are hereby incorporated by reference.

### BACKGROUND

Semiconductor devices are widely used in the electronics industry due to their small size, multi-functional characteristics and/or low manufacturing costs. Semiconductor devices may be classified into semiconductor memory devices that store logical data, semiconductor logical devices that perform a logical data operation process, and hybrid semiconductor devices including memory elements and logical elements.

In view of recent trends in electronic devices towards higher operating with lower power consumption, many contemporary and emerging semiconductor devices are required to operate at high speed and/or at low operating voltages. Further, it is necessary to increase the integration density of many semiconductor devices. However, as the integration density of semiconductor devices increases, some semiconductor devices may suffer from deterioration in electrical performance and reduced reliability.

### SUMMARY

Some aspects of this disclosure provide a semiconductor device with improved electrical characteristics and integration.

A semiconductor device according to some implementations of this disclosure may include a substrate, a transistor on the substrate, a bit line structure electrically connected to the transistor, a channel layer on the bit line structure, a gate structure intersecting the bit line structure, a first conductive line electrically connecting the transistor and the bit line structure, an upper shield line overlapping the first conductive line, and side shield lines spaced apart from each other with the first conductive line interposed therebetween, and the upper shield line and the side shield lines may be electrically separated from the first conductive line and the bit line structure.

A semiconductor device according to some implementations of this disclosure may include a substrate, a first transistor on the substrate, a bit line structure electrically connected to the first transistor, a channel layer on the bit line structure, a gate structure intersecting the bit line structure, a first conductive line and a second conductive line electrically connecting the first transistor and the bit line structure, an upper shield line overlapping the first conductive line, and side shield lines spaced apart from each other with the first conductive line interposed therebetween, the upper shield line may be positioned at the same level as the second conductive line, and the first conductive line may be positioned at the same level as the side shield lines.

A semiconductor device according to some implementations of this disclosure may include a substrate, a first transistor and a second transistor on the substrate, a bit line structure electrically connected to the first transistor, a channel layer on the bit line structure, a gate structure intersecting the bit line structure, a data storage structure electrically connected to the channel layer, a first conductive line and a second conductive line electrically connecting the first transistor and the bit line structure, an upper shield line and side shield lines electrically connected to the second transistor, a first lower insulating layer surrounding the first conductive line and the side shield lines, and a second lower insulating layer surrounding the second conductive line and the upper shield line, the upper shield line may overlap the first conductive line, and the side shield lines may be spaced apart from each other with the first conductive line interposed therebetween.

### BRIEF DESCRIPTION OF THE DRAWINGS

Implementations will be more clearly understood from the following brief description taken in conjunction with the accompanying drawings. The accompanying drawings represent non-limiting examples, as described herein.

FIG. 1 is a block diagram of a semiconductor device according to some implementations.

FIGS. 2 and 3 are schematic perspective views of a semiconductor device according to some implementations.

FIG. 4A is a plan view of a semiconductor device according to some implementations.

FIG. 4B is an enlarged view of region ‘E1’ in FIG. 4A.

FIG. 4C is a cross-sectional view taken along line A-A′ of FIG. 4B.

FIG. 4D is a cross-sectional view taken along line B-B′ in FIG. 4B.

FIGS. 5A and 5B are cross-sectional views of a semiconductor device according to some implementations.

FIGS. 6A and 6B are cross-sectional views of a semiconductor device according to some implementations.

FIG. 7A is a cross-sectional view of a semiconductor device according to some implementations.

FIG. 7B is an enlarged view of region ‘E2’ in FIG. 7A.

FIG. 7C is an enlarged cross-sectional view of the semiconductor device according to FIG. 7A.

FIG. 8 is a cross-sectional view of a semiconductor device according to some implementations.

### DETAILED DESCRIPTION

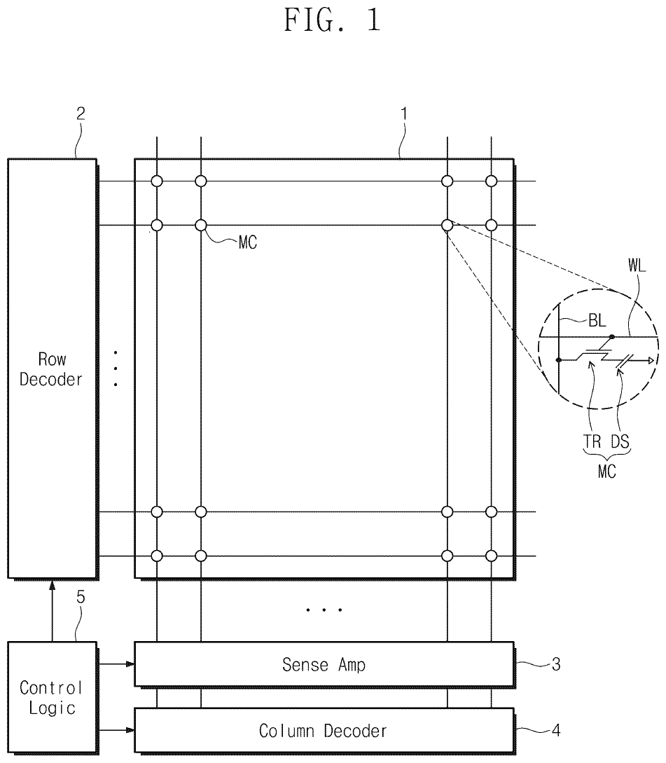

FIG. 1 is a block diagram of a semiconductor device according to some implementations.

Referring to FIG. 1, a semiconductor device may include a memory cell array 1, a row decoder 2, a sense amplifier 3, a column decoder 4, and a control logic 5.

The memory cell array 1 may include a plurality of memory cells MC, which are two-dimensionally or three-dimensionally arranged. Each of the memory cells MC may be provided between and connected to a word line WL and a bit line BL, which are disposed to cross each other.

Each of the memory cells MC may include a selection element TR and a data storage device DS, which are electrically connected in series. The selection element TR may be electrically connected to both the data storage device DS and the word line WL. For example, the selection element TR may be provided at a point where the word line WL and the bit line BL intersect each other.

The selection element TR may include a field effect transistor. The data storage device DS may include at least one of a capacitor, a magnetic tunnel junction pattern, or a variable resistor. As an example, the selection element TR may include a transistor, a gate electrode of the transistor may be connected to the word line WL, and drain/source terminals of the transistor may be respectively connected to the bit line BL and the data storage device DS.

The row decoder 2 may be configured to decode address information, which is input from the outside, and to select one of the word lines WL of the memory cell array 1, based on the decoded address information. The address information decoded by the row decoder 2 may be provided to a row driver, and in this case, the row driver may provide respective voltages to the selected one of the word lines WL and the unselected ones of the word lines WL, in response to the control of a control circuit.

The sense amplifier 3 may be configured to sense, amplify, and output a difference in voltage between one of the bit lines BL, which is selected based on address information decoded by the column decoder 4, and a reference bit line.

The column decoder 4 may provide a data transmission path between the sense amplifier 3 and an external device (e.g., a memory controller). The column decoder 4 may be configured to decode address information, which is input from the outside, and to select one of the bit lines BL, based on the decoded address information.

The control logic 5 may be configured to generate control signals, which are used to control data writing or reading operations on the memory cell array 1.

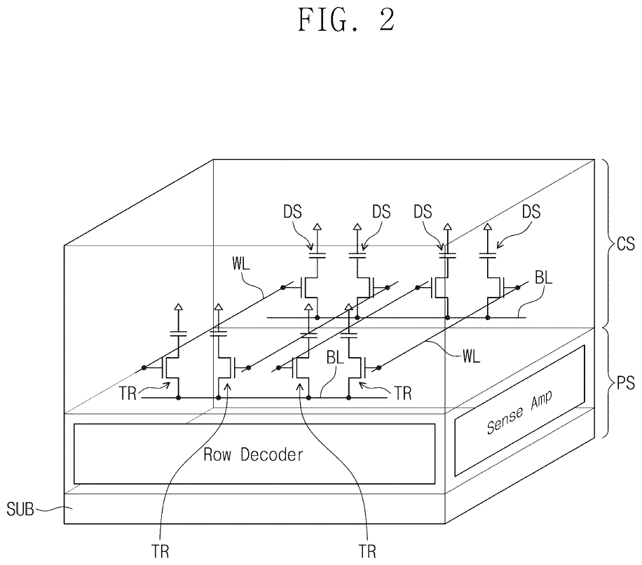

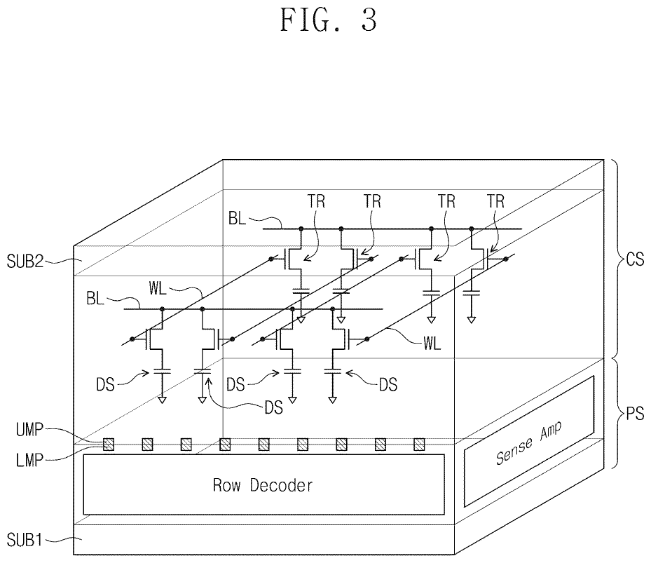

FIGS. 2 and 3 are schematic perspective views of a semiconductor device according to some implementations.

Referring to FIGS. 2 and 3, a semiconductor device may include a peripheral circuit structure PS and a cell array structure CS connected to the peripheral circuit structure PS.

The peripheral circuit structure PS may include core and peripheral circuits, which are formed on a semiconductor substrate SUB. The core and peripheral circuits may include the row and column decoders 2 and 4, the sense amplifier 3, and the control logic 5 described with reference to FIG. 1.

The cell array structure CS may include the memory cell array 1 including the memory cells MC of FIG. 1, which are two- or three-dimensionally arranged on a plane parallel to two different directions (e.g., first and second directions D1 and D2). Each of the memory cells MC may include the selection element TR and the data storage device DS, as described above.

In some implementations, a vertical channel transistor (VCT) may be provided as the selection element TR of each memory cell MC. The vertical channel transistor may be a transistor whose channel region is extended in a direction perpendicular to an upper surface of the semiconductor substrate SUB. In addition, a capacitor may be provided as the data storage element DS of each memory cell MC.

As shown in the example of FIG. 2, in some implementations, the peripheral circuit structure PS may be provided on the substrate SUB, and the cell array structure CS may be provided on the peripheral circuit structure PS.

As shown in the example of FIG. 3, in some implementations, the peripheral circuit structure PS may be provided on a first substrate SUB1, and the cell array structure CS may be provided on a second substrate SUB2. The first substrate SUB1 and the second substrate SUB2 may face each other.

First metal pads LMP may be provided at the uppermost portion of the peripheral circuit structure PS. The first metal pads LMP may be electrically connected to the core and peripheral circuits 2, 3, 4, and 5.

Second metal pads UMP may be provided at the lowermost portion of the cell array structure CS. The second metal pads UMP may be electrically connected to the memory cell array 1. For example, the second metal pads UMP may be in direct contact with and bond to first metal pads LMP of the peripheral circuit structure PS.

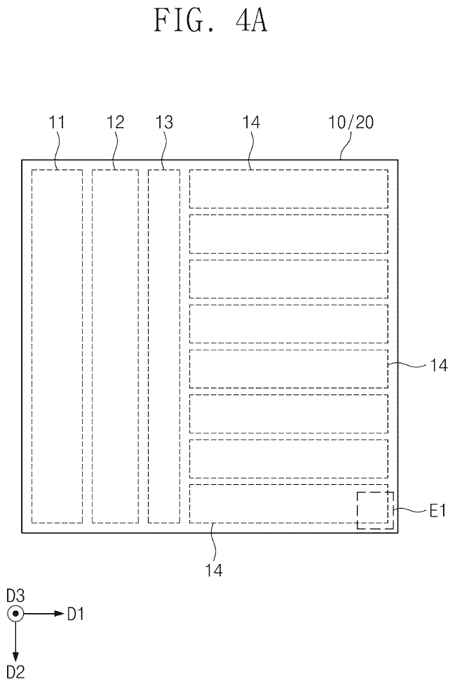

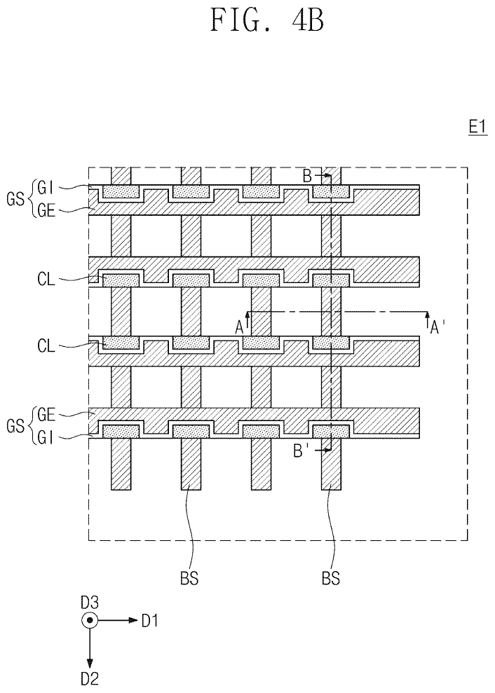

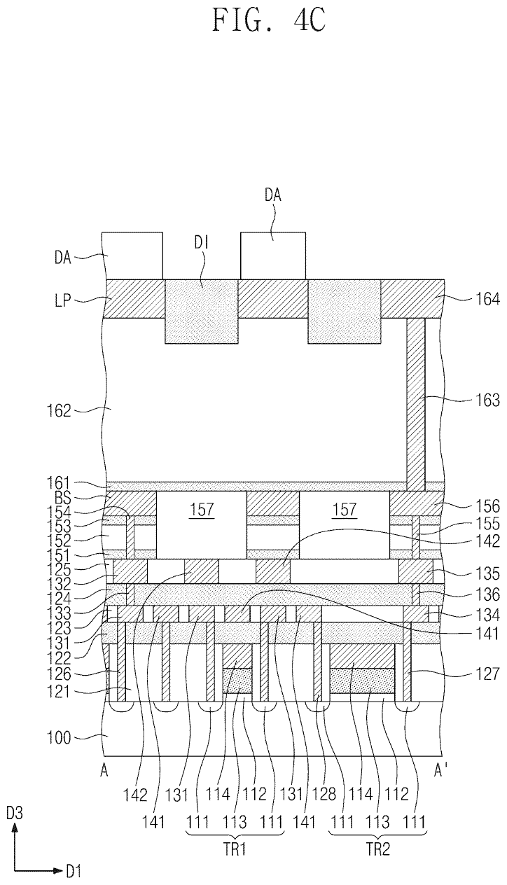

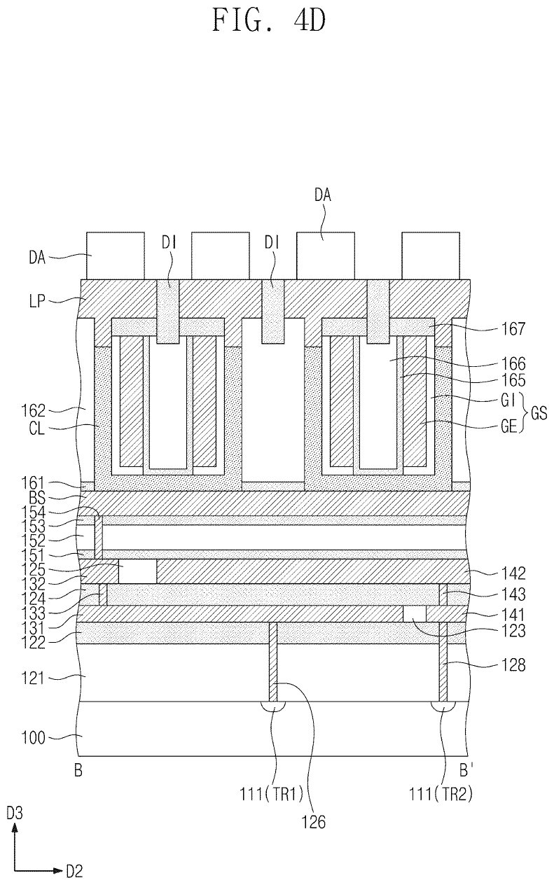

FIG. 4A is a plan view of a semiconductor device according to some implementations. FIG. 4B is an enlarged view of region ‘E1’ in FIG. 4A. FIG. 4C is a cross-sectional view taken along line A-A′ of FIG. 4B. FIG. 4D is a cross-sectional view taken along line B-B′ in FIG. 4B.

Referring to FIGS. 4A to 4D, a semiconductor device may include a peripheral circuit structure 10 and a cell array structure 20 on the peripheral circuit structure 10. The peripheral circuit structure 10 may include a sub-word line driver region 11, a row decoder region 12, a control logic region 13, and sense amplifier regions 14. The sub-word line driver region 11, row decoder region 12, control logic region 13, and sense amplifier regions 14 may be two-dimensionally divided regions defined by a first direction D1 and a second direction D2. The first direction D1 and the second direction D2 may intersect each other. For example, the first direction D1 and the second direction D2 may be horizontal directions perpendicular to each other. The sub-word line driver region 11, row decoder region 12, control logic region 13, and sense amplifier regions 14 may overlap the cell array structure 20 in a third direction D3 (e.g., may be under the cell array structure 20). The third direction D3 may intersect the first direction D1 and the second direction D2. For example, the third direction D3 may be a vertical direction perpendicular to the first direction D1 and the second direction D2.

A sub word line driver may be placed in the sub word line driver region 11. A row decoder may be placed in the row decoder region 12. A control logic may be placed in the control logic region 13. A sense amplifier may be placed in the sense amplifier region 14. These and other elements of the semiconductor device of FIGS. 4A-4D can have the characteristics and arrangement described for corresponding elements of the devices of FIGS. 1-3, except where indicated otherwise.

In some implementations, only the sense amplifier regions 14 may overlap (e.g., be under) the cell array structure 20 in the third direction D3, and the sub word line driver region 11, the row decoder region 12, and the control logic region 13 may not overlap (e.g., may be horizontally spaced apart from) the cell array structure 20 in the third direction D3.

As shown in FIG. 4C, a substrate 100 may be provided. The substrate 100 may be, for example, a semiconductor substrate, an insulator substrate, a silicon-on-insulator (SOI) substrate, or a germanium-on-insulator (GOI) substrate.

A first lower insulating layer 121 on the substrate 100, a first lower capping layer 122 on the first lower insulating layer 121, a second lower insulating layer 123 on the first lower capping layer 122, a second lower capping layer 124 on the second lower insulating layer 123, and a third lower insulating layer 125 on the second lower capping layer 124 may be provided.

The first to third lower insulating layers 121, 123, and 125 may include an insulating material. As an example, the first to third lower insulating layers 121, 123, and 125 may include an oxide.

The first and second lower capping layers 122 and 124 may include an insulating material different from that of the first to third lower insulating layers 121, 123, and 125. As an example, the first and second lower capping layers 122 and 124 may include a nitride.

In some implementations, each of the first to third lower insulating layers 121, 123, and 125 and the first and second lower capping layers 122 and 124 may be a multilayer structure including a plurality of insulating layers.

A first transistor TR1 and a second transistor TR2 may be provided on the substrate 100. Each of the first and second transistors TR1 and TR2 may include impurity regions 111, a peripheral gate insulating layer 112, a first peripheral gate electrode layer 113, and a second peripheral gate electrode layer 114. The impurity regions 111 may be formed by doping the substrate 100 with impurities. The peripheral gate insulating layer 112 may include an insulating material. The first and second peripheral gate electrode layers 113 and 114 may include a conductive material. As an example, the first peripheral gate electrode layer 113 may include polysilicon, and the second peripheral gate electrode layer 114 may include metal. In some implementations, the first transistor TR1 may be a transistor that constitutes a sense amplifier.

A first transistor contact 126, a second transistor contact 127, and a third transistor contact 128 penetrating/extending through the first lower insulating layer 121 and the first lower capping layer 122 may be provided. The first to third transistor contacts 126, 127, and 128 may be surrounded (e.g., laterally surrounded) by the first lower insulating layer 121 and the first lower capping layer 122. The first transistor contact 126 may be electrically connected to the impurity region 111 of the first transistor TR1. The second transistor contact 127 may be electrically connected to the impurity region 111 of the second transistor TR2. The third transistor contact 128 may be electrically connected to the impurity region 111 of the second transistor TR2. The first to third transistor contacts 126, 127, and 128 may include a conductive material.

A first conductive line 131, a second conductive line 134, and a side shield line 141 may be provided in the second lower insulating layer 123. The first conductive line 131, the second conductive line 134, and the side shield line 141 may be surrounded (e.g., laterally surrounded) by the second lower insulating layer 123. The first conductive line 131, the second conductive line 134, and the side shield line 141 may be positioned at the same level. Lower surfaces of the first conductive line 131, the second conductive line 134, and the side shield line 141 may be coplanar. The lower surfaces of the first conductive line 131, the second conductive line 134, and the side shield line 141 may be in contact with an upper surface of the first lower capping layer 122. Upper surfaces of the first conductive line 131, the second conductive line 134, and the side shield line 141 may be coplanar. The upper surfaces of the first conductive line 131, the second conductive line 134, and the side shield line 141 may be in contact with a lower surface of the second lower capping layer 124.

A distance between the first conductive line 131 and the substrate 100 in the third direction D3, a distance between the second conductive line 134 and the substrate 100 in the third direction D3, and a distance between the side shield line 141 and the substrate 100 in the third direction D3 may be the same. The first conductive line 131, the second conductive line 134, and the side shield line 141 may include the same conductive material. For example, the first conductive line 131, the second conductive line 134, and the side shield line 141 may include metal (e.g., the same metal).

The first conductive line 131, the second conductive line 134, and the side shield line 141 may be arranged to be spaced apart in the first direction D1, e.g., horizontally spaced apart. The first conductive line 131, the second conductive line 134, and the side shield line 141 may extend in the second direction D2. A length of each of the first conductive line 131, the second conductive line 134, and the side shield line 141 in the second direction D2 may be greater than a length of each of the first conductive line 131, the second conductive line 134, and the side shield line 141 in the first direction D1.

The first conductive line 131 may be disposed between two side shield lines 141 adjacent to each other in the first direction D1. The first conductive lines 131 and side shield lines 141 may be alternately arranged in the first direction D1. The side shield lines 141 disposed on both sides of the first conductive line 131 may be spaced apart from each other in the first direction D1 with the first conductive line 131 interposed therebetween (e.g., horizontally spaced apart).

The first conductive line 131 may be electrically connected to the first transistor contact 126. A lower surface of the first conductive line 131 may be in contact with an upper surface of the first transistor contact 126. The second conductive line 134 may be electrically connected to the second transistor contact 127. A lower surface of the second conductive line 134 may be in contact with an upper surface of the second transistor contact 127. The side shield line 141 may be electrically connected to the second transistor contact 127. A lower surface of the side shield line 141 may be in contact with an upper surface of the third transistor contact 128.

A first contact 133 and a second contact 136 penetrating/extending through the second lower capping layer 124 may be provided. The first and second contacts 133 and 136 may be surrounded (e.g., laterally surrounded) by the second lower capping layer 124. The first contact 133 may be electrically connected to the first conductive line 131. A lower surface of the first contact 133 may be in contact with the upper surface of the first conductive line 131. The second contact 136 may be electrically connected to the second conductive line 134. A lower surface of the second contact 136 may be in contact with the upper surface of the second conductive line 134. The first and second contacts 133 and 136 may include a conductive material.

A third conductive line 132, a fourth conductive line 135, and an upper shield line 142 may be provided in the third lower insulating layer 125. The third conductive line 132, the fourth conductive line 135, and the upper shield line 142 may be surrounded by the third lower insulating layer 125. The third conductive line 132, the fourth conductive line 135, and the upper shield line 142 may be positioned at the same level. Lower surfaces of the third conductive line 132, the fourth conductive line 135, and the upper shield line 142 may be coplanar. The lower surfaces of the third conductive line 132, the fourth conductive line 135, and the upper shield line 142 may be in contact with an upper surface of the second lower capping layer 124. Upper surfaces of the third conductive line 132, the fourth conductive line 135, and the upper shield line 142 may be coplanar. A lower surface of the upper shield line 142 may face an upper surface of the first conductive line 131.

A distance between the third conductive line 132 and the substrate 100 in the third direction D3, a distance between the fourth conductive line 135 and the substrate 100 in the third direction D3, and a distance between the upper shield line 142 and the substrate 100 in the third direction D3 may be the same. The third conductive line 132, fourth conductive line 135, and upper shield line 142 may include the same conductive material. For example, the third conductive line 132, the fourth conductive line 135, and the upper shield line 142 may include metal (e.g., the same metal).

The third conductive line 132, the fourth conductive line 135, and the upper shield line 142 may be disposed to be spaced apart in the first direction D1. The third conductive line 132, the fourth conductive line 135, and the upper shield line 142 may extend in the second direction D2. A length of each of the third conductive line 132, the fourth conductive line 135, and the upper shield line 142 in the second direction D2 may be greater than a length of each of the third conductive line 132, the fourth conductive line 135, and the upper shield line 142 in the first direction D1. The upper shield line 142 may overlap the first conductive line 131 in the third direction D3.

The third conductive line 132 may be electrically connected to the first contact 133. A lower surface of the third conductive line 132 may be in contact with an upper surface of the first contact 133. The fourth conductive line 135 may be electrically connected to the second contact 136. A lower surface of the fourth conductive line 135 may be in contact with an upper surface of the second contact 136.

A third contact 143 penetrating/extending through the second lower capping layer 124 may be provided. The third contact 143 may be surrounded (e.g., laterally surrounded) by the second lower capping layer 124. The third contact 143 may be electrically connected to the upper shield line 142 and the side shield line 141. An upper surface of the third contact 143 may be in contact with the lower surface of the upper shield line 142. A lower surface of the third contact 143 may be in contact with the upper surface of the side shield line 141. The third contact 143 may include a conductive material.

The upper shield line 142 may be electrically connected to the second transistor TR2 through the third contact 143, the side shield line 141, and the third transistor contact 128. Power may be applied to the upper shield line 142 and the side shield line 141 through the second transistor TR2.

Intervening insulating layers 157 may be provided on the third lower insulating layer 125. The intervening insulating layers 157 may include an insulating material.

First interlayer insulating layers 151, second interlayer insulating layers 152, and third interlayer insulating layers 153 may be provided. The first interlayer insulating layer 151 may be provided on the third lower insulating layer 125. The second interlayer insulating layer 152 may be provided on the first interlayer insulating layer 151. The third interlayer insulating layer 153 may be provided on the second interlayer insulating layer 152. The first to third interlayer insulating layers 151, 152, and 153 may be disposed between intervening insulating layers 157 adjacent to each other in the first direction D1. The first to third interlayer insulating layers 151, 152, and 153 may include an insulating material.

Bit line structures BS and a connection line 156 may be provided. The bit line structure BS may be provided on the third interlayer insulating layer 153. The connection line 156 may be provided on the third interlayer insulating layer 153. The bit line structures BS and the connection line 156 may extend in the second direction D2. The bit line structures BS and the connection line 156 may be arranged to be spaced apart in the first direction D1. The bit line structures BS and the connection line 156 may include a conductive material. The bit line structure BS may be a single conductive layer or multiple conductive layers.

A first connection contact 154 and a second connection contact 155 penetrating/extending through the first to third interlayer insulating layers 151, 152, and 153 may be provided. The first connection contact 154 may be electrically connected to the third conductive line 132 and the bit line structure BS. A lower surface of the first connection contact 154 may be in contact with an upper surface of the third conductive line 132. An upper surface of the first connection contact 154 may be in contact with a lower surface of the bit line structure BS. The second connection contact 155 may be electrically connected to the fourth conductive line 135 and the connection line 156. A lower surface of the second connection contact 155 may be in contact with an upper surface of the fourth conductive line 135. An upper surface of the second connection contact 155 may be in contact with a lower surface of the connection line 156. The first and second connection contacts 154 and 155 may include a conductive material.

Channel layers CL (e.g., as shown in FIG. 4D) may be provided on the bit line structures BS. A plurality of channel layers CL may be in contact with one bit line structure BS. The channel layers CL provided on one bit line structure BS may be arranged in the second direction D2.

The channel layer CL may include a semiconductor material or an oxide semiconductor material. The oxide semiconductor material may include, for example, at least one of InGaZnO, InGaSiO, InSnZnO, InZnO, ZnO, ZnSnO, ZnON, ZrZnSnO, SnO, HfInZnO, GaZnSnO, AlZnSnO, YbGaZnO, or InGaO. The semiconductor material may include, for example, at least one of Si or Ge. In some implementations, the channel layer CL may be a multilayer structure including a plurality of material layers. In some implementations, the channel layer CL may include a two-dimensional material.

Gate structures GS (e.g., as shown in FIG. 4B) may be provided on the channel layers CL. The gate structure GS may extend in the first direction D1. The gate structure GS may intersect the bit line structure BS. The gate structure GS may include a gate insulating layer GI on the channel layer CL and a gate electrode layer GE on the gate insulating layer GI. The gate insulating layer GI may include an insulating material. As an example, the gate insulating layer GI may include oxide.

The gate electrode layer GE may include a conductive material. For example, the gate electrode layer GE may be made of a doped semiconductor material (e.g., doped silicon, doped germanium, etc.), a conductive metal nitride (e.g., titanium nitride, tantalum nitride, etc.), or a metal (e.g., tungsten, titanium, tantalum, etc.), or a metal-semiconductor compound (e.g., tungsten silicide, cobalt silicide, titanium silicide, etc.).

First molding insulating layers 165 and second molding insulating layers 166 may be provided. The first molding insulating layer 165 may be provided on the channel layer CL and the gate structures GS. The second molding insulating layer 166 may be provided on the first molding insulating layer 165. A gate capping layer 167 may be provided on the first molding insulating layer 165, the second molding insulating layer 166, and the gate electrode layers GE. The first molding insulating layer 165, the second molding insulating layer 166, and the gate capping layer 167 may include an insulating material.

A fourth interlayer insulating layer 161 may be provided on the bit line structure BS. The channel layer CL may penetrate/extend through the fourth interlayer insulating layer 161. Third molding insulating layers 162 may be provided on the fourth interlayer insulating layer 161. The fourth interlayer insulating layer 161 and the third molding insulating layer 162 may include an insulating material.

Landing pads LP (e.g., as shown in FIG. 4C) may be provided. The landing pad LP may be provided on the channel layer CL and the gate capping layer 167. The landing pad LP may be electrically connected to the channel layer CL. The landing pad LP may include a conductive material. In some implementations, the landing pad LP may include a barrier layer and a conductive layer on the barrier layer. As an example, the barrier layer of the landing pad LP may include at least one of titanium or tantalum, and the conductive layer of the landing pad LP may include tungsten.

A connection pad 164 may be provided. The connection pad 164 may be provided on the third molding insulating layer 162. The connection pad 164 may be positioned at a higher level than the channel layer CL. The connection pad 164 may be positioned at the same level as the landing pad LP. The connection pad 164 may be electrically connected to an external power supply device. The connection pad 164 may include a conductive material.

A third connection contact 163 penetrating/extending through the third molding insulating layer 162 and the fourth interlayer insulating layer 161 may be provided. The third connection contact 163 may be electrically connected to the connection line 156 and the connection pad 164. The third connection contact 163 may include a conductive material.

The external power supply device may supply power to the side shield line 141 and the upper shield line 142 through to the connection pad 164, the third connection contact 163, the connection line 156, the second connection contact 155, the fourth conductive line 135, the second contact 136, the second connection contact 155, the second transistor TR2, and the third transistor contact 128.

Separation structures DI may be provided to separate the landing pads LP and the connection pad 164. The separation structure DI may include an insulating material. In some implementations, the separation structure DI may be a multilayer including a plurality of insulating layers.

Data storage structures DA may be provided, e.g., as shown in FIG. 4D. The data storage structure DA may be connected to the landing pad LP. In some implementations, the data storage structure DA may be a capacitor. In this case, the data storage structure DA may include a lower electrode, an upper electrode, and a capacitor dielectric layer interposed therebetween. In some implementations, the data storage structure DA may be a variable resistance pattern that may be switched between two resistance states by an electrical pulse. In this case, the data storage structure DA can be a phase-change material, a perovskite compound, a transition metal oxide, a magnetic material, a ferromagnetic material, or an antiferromagnetic material whose crystal state changes depending on the amount of current.

The data storage structure DA may be electrically connected to the first transistor TR1 through the landing pad LP, the channel layer CL, the bit line structure BS, the first connection contact 154, the third conductive line 132, the first contact 133, the first conductive line 131, and the first transistor contact 126.

The upper shield line 142, the third contact 143, and the side shield line 141 may be electrically separated/isolated from the data storage structure DA, the landing pad LP, the channel layer CL, the bit line structure BS, the first connection contact 154, the third conductive line 132, the first contact 133, the first conductive line 131, the first transistor contact 126, and the first transistor TR1.

In a semiconductor device according to some implementations, the side shield lines 141 may be disposed on both sides of the first conductive line 131 and the upper shield line 142 may be disposed on the first conductive line 131, thereby preventing or reducing coupling between adjacent first conductive lines 131. Accordingly, parasitic capacitance between the first conductive lines 131 may be prevented or reduced.

Power may be applied to the side shield line 141 and the upper shield line 142, thereby improving a shielding effect of the side shield line 141 and the upper shield line 142.

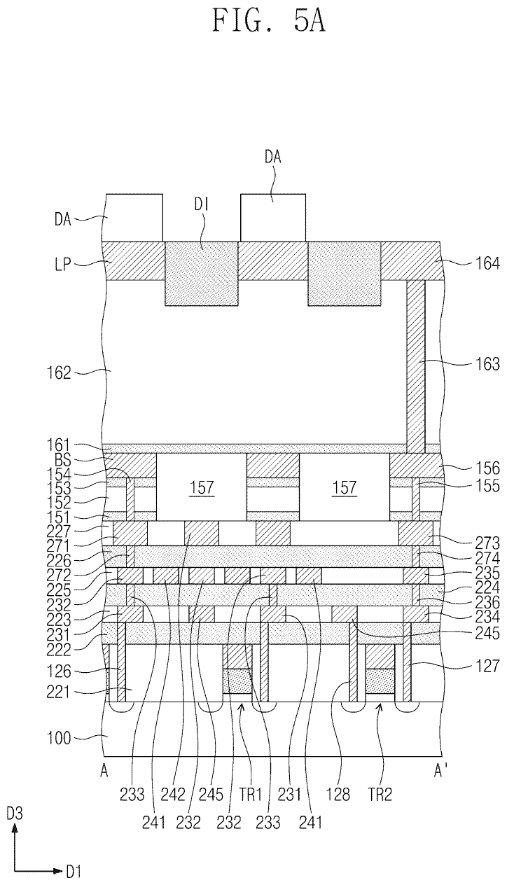

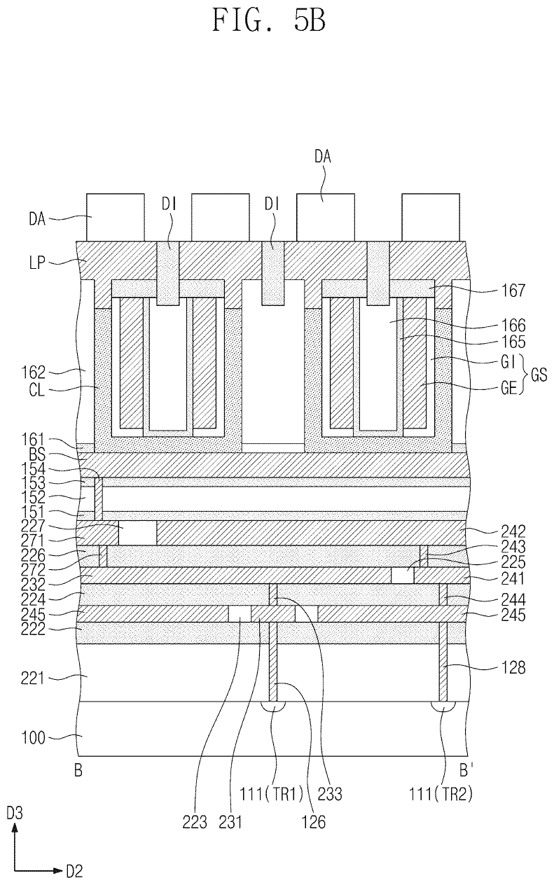

FIGS. 5A and 5B are cross-sectional views of a semiconductor device according to some implementations. The semiconductor devices according to FIGS. 5A and 5B may be similar to the semiconductor device according to FIGS. 4A through 4D, except as described below.

Referring to FIGS. 5A and 5B, a first lower insulating layer 221 on a substrate 100, a first lower capping layer 222 on the first lower insulating layer 221, a second lower insulating layer 223 on the first lower capping layer 222, a second lower capping layer 224 on the second lower insulating layer 223, a third lower insulating layer 225 on the second lower capping layer 224, a third lower insulating layer 225 on the third lower insulating layer 225, a third lower capping layer 226 on the third lower insulating layer 225, and a fourth lower insulating layer 227 on the third lower capping layer 226 may be provided.

A first conductive line 231, a second conductive line 234, and a lower shield line 245 may be provided in the second lower insulating layer 223. The first conductive line 231 may be electrically connected to a first transistor TR1 through a first transistor contact 126. The second conductive line 234 may be electrically connected to a second transistor TR2 through a second transistor contact 127. The lower shield line 245 may be electrically connected to the second transistor TR2 through a third transistor contact 128.

A third conductive line 232, a fourth conductive line 235, and a side shield line 241 may be provided in the third lower insulating layer 225. The third conductive line 232 may be disposed between two side shield lines 241 adjacent to each other in the first direction D1. The third conductive line 232 may overlap the lower shield line 245 in the third direction D3.

A first contact 233 and a second contact 236 penetrating/extending through the second lower capping layer 224 may be provided. The first contact 233 may be electrically connected to the first conductive line 231 and the third conductive line 232. The second contact 236 may be electrically connected to the second conductive line 234 and the fourth conductive line 235.

A third contact 244 penetrating/extending through the second lower capping layer 224 may be provided. The third contact 244 may electrically connect the side shield line 241 and the lower shield line 245.

A fifth conductive line 271, a sixth conductive line 273, and an upper shield line 242 may be provided in the fourth lower insulating layer 227. The upper shield line 242 may overlap the third conductive line 232 and the lower shield line 245 in the third direction D3. The third conductive line 232 may be disposed between the lower shield line 245 and the upper shield line 242.

A fourth contact 272 and a fifth contact 274 penetrating/extending through the third lower capping layer 226 may be provided. The fourth contact 272 may be electrically connected to the third conductive line 232 and the fifth conductive line 271. The fifth contact 274 may be electrically connected to the fourth conductive line 235 and the sixth conductive line 273.

A sixth contact 243 penetrating/extending through the third lower capping layer 226 may be provided. The sixth contact 243 may electrically connect the upper shield line 242 and the side shield line 241.

The upper shield line 242, the sixth contact 243, the side shield line 241, the third contact 244, the lower shield line 245, and the third transistor contact 128 may be connected to the second transistor TR2, and power may be applied to the second transistor TR2.

The fifth conductive line 271 may be electrically connected to a bit line structure BS through a first connection contact 154. The sixth conductive line 273 may be electrically connected to a connection line 156 through a second connection contact 155.

In the semiconductor device according to some implementations, the side shield lines 241 may be disposed on both sides of the third conductive line 232, and the upper shield line 242 and the lower shield may be disposed above and below the third conductive line 232, thereby preventing or reducing coupling between adjacent third conductive lines 232. Power may be applied to the side shield line 241, lower shield line 245, and upper shield line 242, thereby improving shielding effect of the side shield line 241, lower shield line 245, and upper shield line 242.

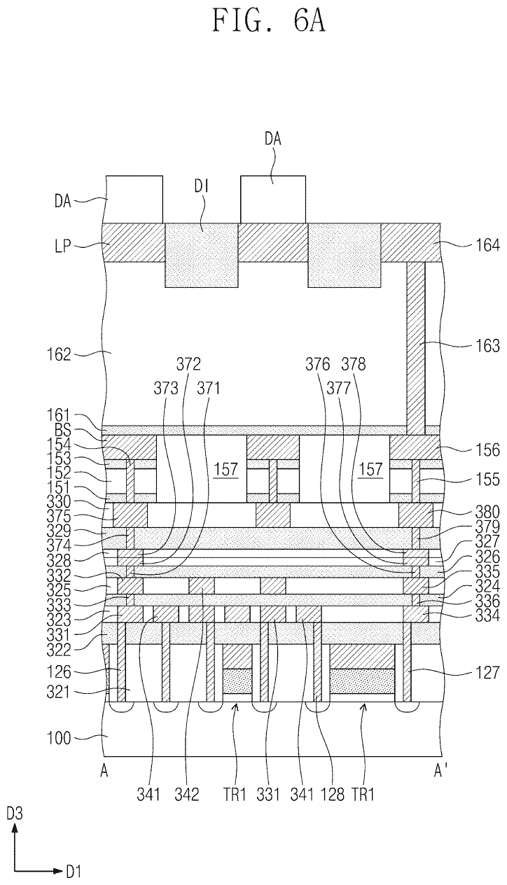

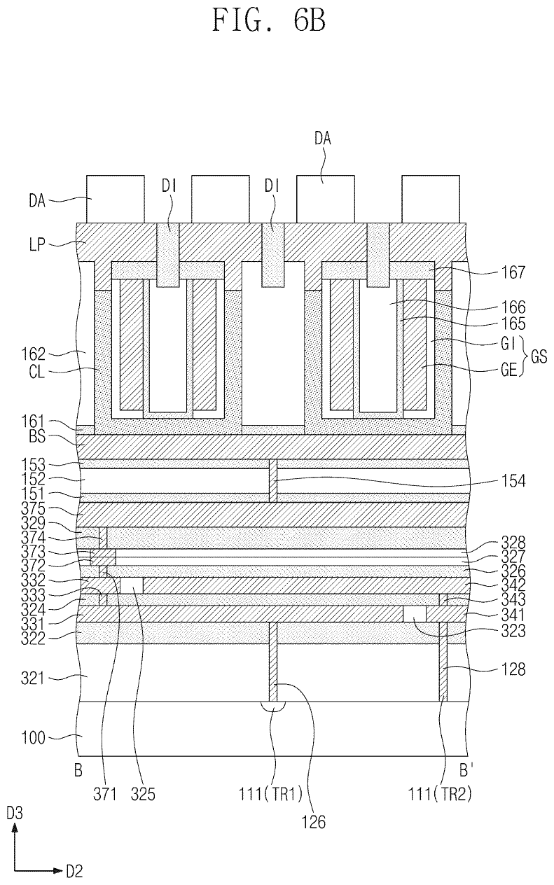

FIGS. 6A and 6B are cross-sectional views of a semiconductor device according to some implementations. The semiconductor device according to FIGS. 6A and 6B may be similar to the semiconductor device according to FIGS. 4A through 4D except as described below.

Referring to FIGS. 6A and 6B, a first lower insulating layer 321 on a substrate 100, a first lower capping layer 322 on the first lower insulating layer 321, a second lower insulating layer 323 on the first lower capping layer 322, a second lower capping layer 324 on the second lower insulating layer 323, a third lower insulating layer 325 on the second lower capping layer 324, a third lower capping layer 326 on the third lower insulating layer 325, a first bonding insulating layer 327 on the third lower capping layer 326, a second bonding insulating layer 328 on the first bonding insulating layer 327, a fourth lower capping layer 329 on the second bonding insulating layer 328, and a fourth lower insulating layer 330 on the fourth lower capping layer 329 may be provided.

A first conductive line 331, a second conductive line 334, and a side shield line 341 may be provided in the second lower insulating layer 323. The first conductive line 331 may be disposed between two side shield lines 341 adjacent to each other in the first direction D1.

A third conductive line 332, a fourth conductive line 335, and an upper shield line 342 may be provided in the third lower insulating layer 325.

A first contact 333 and a second contact 336 penetrating/extending through the second lower capping layer 324 may be provided. The first contact 333 may be electrically connected to the first conductive line 331 and the third conductive line 332. The second contact 336 may be electrically connected to the second conductive line 334 and the fourth conductive line 335.

A first bonding pad 372 and a second bonding pad 377 may be provided in the first bonding insulating layer 327. A third bonding pad 373 and a fourth bonding pad 378 may be provided in the second bonding insulating layer 328. The first bonding pad 372 may be in contact with the third bonding pad 373 through a wafer bonding process. The second bonding pad 377 may be in contact with the fourth bonding pad 378 through a wafer bonding process. The first to fourth bonding pads 372, 377, 373, and 378 may include a conductive material.

A third contact 371 and a fourth contact 376 penetrating/extending through the third lower capping layer 326 may be provided. The third contact 371 may be electrically connected to the first bonding pad 372 and the third conductive line 332. The fourth contact 376 may be electrically connected to the second bonding pad 377 and the fourth conductive line 335.

A fifth conductive line 375 and a sixth conductive line 380 may be provided in the fourth lower insulating layer 330.

A fifth contact 374 and a sixth contact 379 penetrating/extending through the fourth lower capping layer 329 may be provided. The fifth contact 374 may be electrically connected to the third bonding pad 373 and the fifth conductive line 375. The sixth contact 379 may be electrically connected to the fourth bonding pad 378 and the sixth conductive line 380.

The fifth conductive line 375 may be electrically connected to a bit line structure BS through a first connection contact 154. The sixth conductive line 380 may be electrically connected to a connection line 156 through a second connection contact 155.

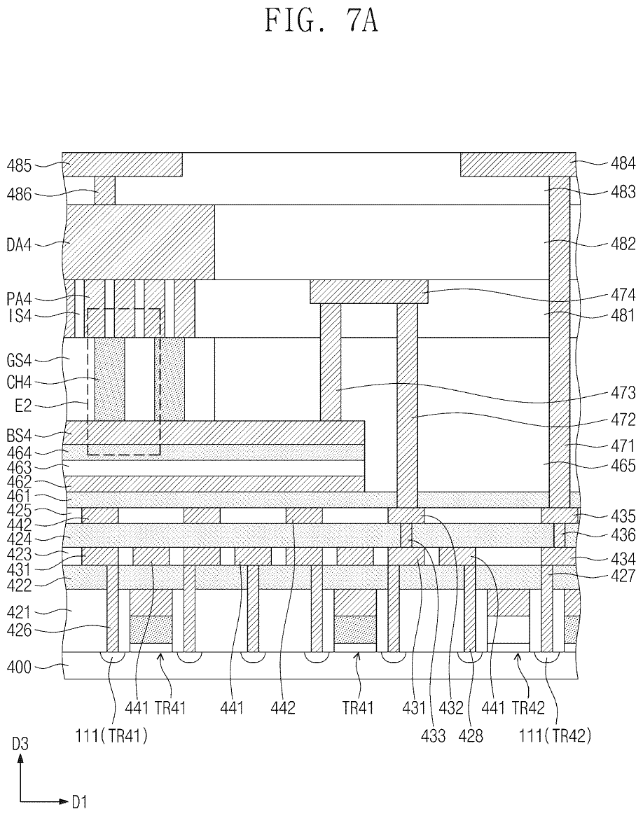

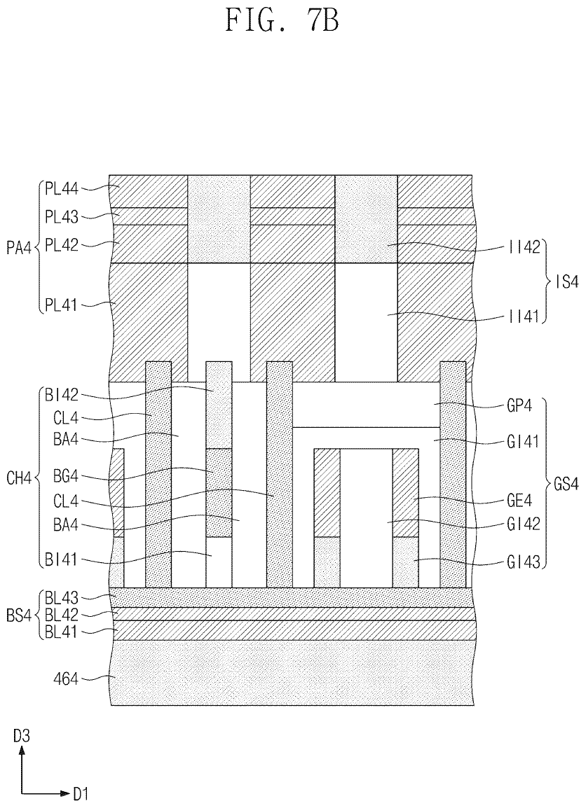

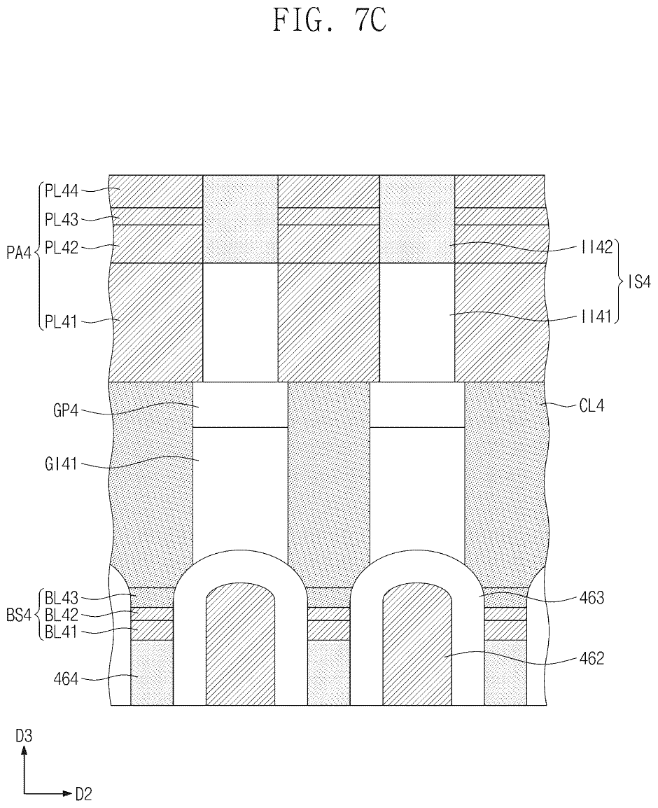

FIG. 7A is a cross-sectional view of a semiconductor device according to some implementations. FIG. 7B is an enlarged view of region ‘E2’ in FIG. 7A. FIG. 7C is an enlarged cross-sectional view of the semiconductor device according to FIG. 7A.

Referring to FIG. 7A, a substrate 400 may be provided. A first lower insulating layer 421 on the substrate 400, a first lower capping layer 422 on the first lower insulating layer 421, a second lower insulating layer 423 on the first lower capping layer 422, and a second lower capping layer 424 on the insulating layer 423, and a third lower insulating layer 425 on the second lower capping layer 424 may be provided.

A first transistor TR41 and a second transistor TR42 may be provided on the substrate 100. In some implementations, the first transistor TR41 may be a transistor that constitutes a sense amplifier.

A first transistor contact 426, a second transistor contact 427, and a third transistor contact 428 penetrating/extending through the first lower insulating layer 421 and the first lower capping layer 422 may be provided. The first transistor contact 426 may be electrically connected to the impurity region 411 of the first transistor TR41. The second transistor contact 427 may be electrically connected to the impurity region 411 of the second transistor TR42. The third transistor contact 428 may be electrically connected to the impurity region 411 of the second transistor TR42.

A first conductive line 431, a second conductive line 434, and a side shield line 441 may be provided in the second lower insulating layer 423. The first conductive line 431 may be disposed between two side shield lines 441 adjacent to each other in the first direction D1.

A third conductive line 432, a fourth conductive line 435, and an upper shield line 442 may be provided in the third lower insulating layer 425.

A first contact 433 and a second contact 436 penetrating/extending through the second lower capping layer 424 may be provided. The first contact 433 may be electrically connected to the first conductive line 431 and the third conductive line 432. The second contact 436 may be electrically connected to the second conductive line 434 and the fourth conductive line 435.

An interlayer insulating layer 461 may be provided on the third lower insulating layer 425. The interlayer insulating layer 461 may include an insulating material. A shield layer 462 may be provided on the interlayer insulating layer 461. The shield layer 462 may include a conductive material. A shield insulating layer 463 may be provided on the shield layer 462. The shield insulating layer 463 may include an insulating material. A bit line capping layer 464 may be provided on the shield insulating layer 463. The bit line capping layer 464 may include an insulating material. A bit line structure BS4 may be provided on the bit line capping layer 464.

A first cover insulating layer 465 may be provided on the interlayer insulating layer 461. A second cover insulating layer 481 may be provided on the first cover insulating layer 465. A third cover insulating layer 482 may be provided on the second cover insulating layer 481. A fourth cover insulating layer 483 may be provided on the third cover insulating layer 482. The first to fourth cover insulating layers 465, 481, 482, and 483 may include an insulating material.

Channel structures CH4 and gate structures GS4 may be provided on the bit line structure BS4. The channel structure CH4 may be disposed between the gate structures GS4. The channel structures CH4 and gate structures GS4 may be surrounded (e.g., laterally surrounded) by the first cover insulating layer 465.

Pad structures PA4 and insulating structures IS4 may be provided on the channel structures CH4 and gate structures GS4. The pad structure PA4 may be disposed between insulating structures IS4. The pad structures PA4 and the insulating structures IS4 may be surrounded (e.g., laterally surrounded) by the second cover insulating layer 481.

A data storage structure DA4 may be provided on the pad structures PA4. The data storage structure DA4 may be surrounded by the third cover insulating layer 482.

A first connection contact 472, a second connection contact 473, and a first connection line 474 may be provided. The first connection contact 472 may be in contact with the third conductive line 432. The second connection contact 473 may be in contact with the bit line structure BS4. The first connection line 474 may be in contact with the first connection contact 472 and the second connection contact 473. The first connection contact 472 and the second connection contact 473 may be surrounded by first and second cover insulating layers 465 and 481. The first connection line 474 may be surrounded by the second cover insulating layer 481.

The data storage structure DA4 may be electrically connected to the first transistor TR41 through the pad structure PA4, the channel structure CH4, the bit line structure BS4, the second connection contact 473, the first connection line 474, the first connection contact 472, the third conductive line 432, the first contact 433, the first conductive line 431, and the first transistor contact 426.

A third connection contact 471 and a connection pad 484 may be provided. The third connection contact 471 may be in contact with the fourth conductive line 435. The connection pad 484 may be in contact with the third connection contact 471. The third connection contact 471 may be surrounded (e.g., laterally surrounded) by first to fourth cover insulating layers 465, 481, 482, and 483. The connection pad 484 may be surrounded (e.g., laterally surrounded) by the fourth cover insulating layer 483.

The connection pad 484 may be electrically connected to the second transistor TR42 through the third connection contact 471, the fourth conductive line 435, the second contact 436, the second conductive line 434, and the second transistor contact 427.

A fourth connection contact 486 and a second connection line 485 may be provided. The fourth connection contact 486 may be in contact with the data storage structure DA4. The second connection line 485 may be in contact with the fourth connection contact 486. The fourth connection contact 486 may be surrounded (e.g., laterally surrounded) by the fourth cover insulating layer 483. The second connection line 485 may be surrounded (e.g., laterally surrounded) by the fourth cover insulating layer 483.

The first to fourth connection contacts 472, 473, 471, and 486, and the first and second connection lines 474 and 485 may include a conductive material.

Referring to FIGS. 7B and 7C, the bit line structure BS4 may include a first bit line layer BL41 on the bit line capping layer 464, a second bit line layer BL42 on the first bit line layer BL41, and a third bit line layer BL43 on the second bit line layer BL42. The first to third bit line layers BL41, BL42, and BL43 may include different conductive materials.

A portion of the shield insulating layer 463 and a portion of the shield layer 462 may be disposed between the bit line capping layers 464 and between the bit line structures BS4.

The channel structure CH4 may include channel layers CL4, backgate spacers BA4, a backgate insulating layer BI41, a backgate electrode layer BG4, and a backgate capping layer BI42. The backgate spacers BA4, the backgate insulating layer BI41, the backgate electrode layer BG4, and the backgate capping layer BI42 may be disposed between the channel layers CL4 in the first direction D1. The backgate insulating layer BI41, the backgate electrode layer BG4, and the backgate capping layer BI42 may be disposed between the backgate spacers BA4 in the first direction D1. The back gate insulating layer BI41 may be disposed on the third bit line layer BL43. The backgate electrode layer BG4 may be disposed on the backgate insulating layer BI41. The backgate capping layer BI42 may be disposed on the backgate electrode layer BG4.

The channel layer CL4 and the back gate electrode layer BG4 may include a conductive material. The backgate spacer BA4, the backgate insulating layer BI41, and the backgate capping layer BI42 may include an insulating material.

The gate structure GS4 may include gate electrode layers GE4, a first gate insulating layer GI41, a second gate insulating layer GI42, a third gate insulating layer GI43, and a gate capping layer GP4. The gate electrode layers GE4, the second gate insulating layer GI42, and the third gate insulating layers GI43 may be disposed in the first gate insulating layer GI41. The first gate insulating layer GI41 may be provided between the gate electrode layer GE4 and the channel layer CL4. The second gate insulating layer GI42 may be provided between the gate electrode layers GE4. The third gate insulating layer GI43 may be disposed between the gate electrode layer GE4 and the bit line structure BS4. The first to third gate insulating layers GI41, GI42, and GI43 and the gate capping layer GP4 may include an insulating material.

The pad structure PA4 may include a first pad layer PL41, a second pad layer PL42 on the first pad layer PL41, a third pad layer PL43 on the second pad layer PL42, and a fourth pad layer PL44 on the third pad layer PL43. The first pad layer PL41 may be in contact with the channel layer CL4. The first and second pad layers PL41 and PL42 may form a node contact. The third and fourth pad layers PL43 and PL44 may form a landing pad. The first to fourth pad layers PL41, PL42, PL43, and PL44 may include a conductive material.

The insulating structure IS4 may include a first insulating layer I141 and a second insulating layer I142 on the first insulating layer I141. The first pad layer PL41 may be disposed between first insulating layers I141. The second to fourth pad layers PL42, PL43, and PL44 may be disposed between second insulating layers I142. The first and second insulating layers I141 and I142 may include an insulating material.

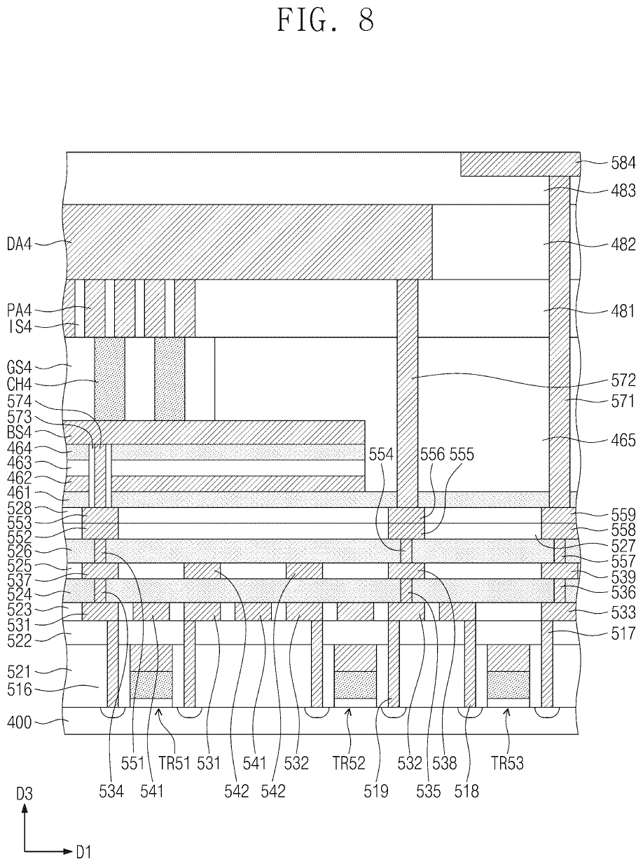

FIG. 8 is a cross-sectional view of a semiconductor device according to some implementations. The semiconductor device according to FIG. 8 may be similar to the semiconductor device according to FIGS. 7A to 7C except as described below.

Referring to FIG. 8, a first transistor TR51, a second transistor TR52, and a third transistor TR53 may be provided on a substrate 400. A first lower insulating layer 521 on the substrate 400, a first lower capping layer 522 on the first lower insulating layer 521, a second lower insulating layer 523 on the first lower capping layer 522, a second lower capping layer 524 on the second lower insulating layer 523, a third lower insulating layer 525 on the second lower capping layer 524, a third lower capping layer 526 on the third lower insulating layer 525, a first bonding insulating layer 527 on the third lower capping layer 526, and a second bonding insulating layer 528 on the first bonding insulating layer 527 may be provided.

A first transistor contact 516, a second transistor contact 517, a third transistor contact 518, and a fourth transistor contact 519 penetrating/extending through the first lower insulating layer 521 and the first lower capping layer 522 may be provided.

A first conductive line 531, a second conductive line 532, a third conductive line 533, and a side shield line 541 may be provided in the second lower insulating layer 523. Each of the first and second conductive lines 531 and 532 may be disposed between two side shield lines 541 adjacent to each other in the first direction D1.

A fourth conductive line 537, a fifth conductive line 538, a sixth conductive line 539, and an upper shield line 542 may be provided in the third lower insulating layer 525. The upper shield line 542 may overlap the first conductive line 531 or the second conductive line 532 in the third direction D3.

A first contact 534, a second contact 535, and a third contact 536 penetrating/extending through the second lower capping layer 524 may be provided.

A first bonding pad 552, a second bonding pad 555, and a third bonding pad 558 may be provided in the first bonding insulating layer 527. A fourth bonding pad 553, a fifth bonding pad 556, and a sixth bonding pad 559 may be provided in the second bonding insulating layer 528. The first bonding pad 552 may be in contact with the fourth bonding pad 553 through a wafer bonding process. The second bonding pad 555 may be in contact with the fifth bonding pad 556 through a wafer bonding process. The third bonding pad 558 may be in contact with the sixth bonding pad 559 through a wafer bonding process.

A fourth contact 551, a fifth contact 554, and a sixth contact 557 penetrating the third lower capping layer 526 may be provided.

A through contact 574 and a through contact insulating layer 573 penetrating/extending through the interlayer insulating layer 461, the shield layer 462, the shield insulating layer 463, and the bit line capping layer 464 may be provided. The through contact 574 may include a conductive material. The through contact insulating layer 573 may surround (e.g., laterally surround) the through contact 574. The through contact insulating layer 573 may include an insulating material.

A first connection contact 572 may be provided in contact with a data storage structure DA4 and the fifth bonding pad 555. A second connection contact 571 may be provided in contact with the sixth bonding pad 559 and a connection pad 584.

The bit line structure BS4 includes a through contact 574, a fourth bonding pad 553, a first bonding pad 552, a fourth contact 551, a fourth conductive line 537, and a first contact 534, may be electrically connected to the first transistor TR51 through the first conductive line 531 and the first transistor contact 516.

The data storage structure DA4 may be electrically connected to the first transistor TR51, through the through contact 574, the fourth bonding pad 553, the first bonding pad 552, the fourth contact 551, the fourth conductive line 537, the first contact 534, first conductive line 531, and the first transistor contact 516.

The connection pad 584 may be electrically connected to the third transistor TR53 through the second connection contact 571, the sixth bonding pad 559, the third bonding pad 558, the sixth contact 557, the sixth conductive line 539, the third contact 536, the third conductive line 533, and the second transistor contact 517.

Power may be applied to the side shield line 541 and the upper shield line 542 through the third transistor TR53.

Accordingly, the semiconductor devices described with respect to FIGS. 4A-8 according to some implementations may prevent or reduce coupling between conductive lines.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples are described above, a person skilled in the art may understand that many modifications and variations are made without departing from the spirit and scope of the following claims. Accordingly, the above examples should be considered in all respects as illustrative and not restrictive.

What is claimed is:

1. A semiconductor device comprising:
a substrate;
a transistor on the substrate;
a bit line structure electrically connected to the transistor;
a channel layer on the bit line structure;
a gate structure intersecting the bit line structure;
a first conductive line electrically connecting the transistor and the bit line structure;
an upper shield line vertically overlapping the first conductive line; and
a plurality of side shield lines spaced horizontally apart from each other with the first conductive line interposed therebetween,
wherein the upper shield line and the plurality of side shield lines are electrically isolated from the first conductive line and the bit line structure.

2. The semiconductor device of claim 1, further comprising a second conductive line electrically connecting the first conductive line and the bit line structure,
wherein a lower surface of the second conductive line and a lower surface of the upper shield line are coplanar.

3. The semiconductor device of claim 2, further comprising a lower insulating layer laterally surrounding the second conductive line and the upper shield line.

4. The semiconductor device of claim 1, wherein lower surfaces of the plurality of side shield lines and a lower surface of the first conductive line are coplanar.

5. The semiconductor device of claim 1, further comprising a lower insulating layer laterally surrounding the plurality of side shield lines and the first conductive line.

6. The semiconductor device of claim 1, further comprising a lower shield line vertically overlapping the first conductive line,
wherein the first conductive line is disposed vertically between the upper shield line and the lower shield line, and
wherein the lower shield line is electrically isolated from the bit line structure and the first conductive line.

7. The semiconductor device of claim 1, wherein the upper shield line and the plurality of side shield lines are configured to receive power from a power supply.

8. A semiconductor device comprising:
a substrate;
a first transistor on the substrate;
a bit line structure electrically connected to the first transistor;
a channel layer on the bit line structure;
a gate structure intersecting the bit line structure;
a first conductive line and a second conductive line electrically connecting the first transistor and the bit line structure;
an upper shield line vertically overlapping the first conductive line; and
a plurality of side shield lines spaced horizontally apart from each other with the first conductive line interposed therebetween,
wherein the upper shield line is positioned at a same vertical level as the second conductive line, and
wherein the first conductive line is positioned at a same vertical level as the plurality of side shield lines.

9. The semiconductor device of claim 8, wherein the upper shield line and the plurality of side shield lines are electrically isolated from the first conductive line, the second conductive line, and the bit line structure.

10. The semiconductor device of claim 8, wherein a lower surface of the upper shield line and an upper surface of the first conductive line face each other.

11. The semiconductor device of claim 8, further comprising:
a lower capping layer between the upper shield line and the first conductive line; and
a first contact extending through the lower capping layer,
wherein the first contact is in contact with an upper surface of the first conductive line and a lower surface of the second conductive line.

12. The semiconductor device of claim 11, wherein the upper surface of the first conductive line and upper surfaces of the plurality of side shield lines are in contact with a lower surface of the lower capping layer, and
wherein the lower surface of the second conductive line and a lower surface of the upper shield line are in contact with an upper surface of the lower capping layer.

13. The semiconductor device of claim 11, further comprising a second contact extending through the lower capping layer,
wherein the second contact is in contact with a lower surface of the upper shield line and an upper surface of one of the plurality of side shield lines.

14. The semiconductor device of claim 8, wherein the bit line structure is positioned at a higher vertical level than the first conductive line, the second conductive line, the upper shield line, and the side shield lines.

15. The semiconductor device of claim 8, further comprising:
a landing pad electrically connected to the channel layer; and
a data storage structure electrically connected to the landing pad.

16. The semiconductor device of claim 8, wherein the first transistor includes an impurity region and a peripheral gate electrode layer, and
wherein the semiconductor device includes a transistor contact electrically connecting the first conductive line and the impurity region.

17. The semiconductor device of claim 8, further comprising a second transistor on the substrate,
wherein the upper shield line and the plurality of side shield lines are configured to receive power through the second transistor.

18. The semiconductor device of claim 8, wherein the bit line structure extends in a first direction,
wherein the gate structure extends in a second direction orthogonal to the first direction, the first direction and the second direction being horizontal directions, and
wherein a length of each of the plurality of side shield lines and the first conductive line in the first direction is greater than a length of each of the plurality of side shield lines and the first conductive line in the second direction.

19. A semiconductor device comprising:
a substrate;
a first transistor and a second transistor on the substrate;
a bit line structure electrically connected to the first transistor;
a channel layer on the bit line structure;
a gate structure intersecting the bit line structure;
a data storage structure electrically connected to the channel layer;
a first conductive line and a second conductive line electrically connecting the first transistor and the bit line structure;
an upper shield line and a plurality of side shield lines electrically connected to the second transistor;
a first lower insulating layer laterally surrounding the first conductive line and the plurality of side shield lines; and
a second lower insulating layer laterally surrounding the second conductive line and the upper shield line,
wherein the upper shield line vertically overlaps the first conductive line, and
wherein the plurality of side shield lines are spaced horizontally apart from each other with the first conductive line interposed therebetween.

20. The semiconductor device of claim 19, further comprising a connection pad positioned at a higher vertical level than the channel layer,
wherein the upper shield line and the plurality of side shield lines are configured to receive power through the connection pad and the second transistor.
